(19) United States
(12) Patent Application Publication
(10) Pub. No.: US 2013/0309803 A1
(43) Pub. Date: Nov. 21, 2013

(54) RADIATION SENSOR WITH PHOTODIODES BEING INTEGRATED ON A SEMICONDUCTOR SUBSTRATE AND CORRESPONDING INTEGRATION PROCESS

(71) Applicant: STMicroelectronics S.r.I., (US)

(72) Inventors: Maria Eloisa Castagna, Catania (IT); Salvatore Leonardi, Aci S. Antonio (IT); Salvatore Abbisso, Augusta (IT); Lidia Maddiona, Catania (IT)

(73) Assignee: STMICROELECTRONICS S.R.L., Agrate Brianza (IT)

(21) Appl. No.: 13/828,170

(22) Filed: Mar. 14, 2013

Related U.S. Application Data
(62) Division of application No. 12/649,256, filed on Dec. 29, 2009.

(30) Foreign Application Priority Data
Dec. 31, 2008 (IT) MI2008A002362

(51) Int. Cl. H01L 31/18

(52) U.S. Cl. CPC H01L 31/18
USPC 438/72

(57) ABSTRACT

An embodiment relates to a sensor integrated on a semiconductor substrate and comprising at least one first and second photodiode including at least one first and one second p-n junction made in such a semiconductor substrate as well as at least one first and one second antireflection coating made on top of such a first and second photodiode. At least one antireflection coating of such a first and second photodiode comprises at least one first and one second different antireflection layer to make a double layer antireflection coating suitable for obtaining for the corresponding photodiode a responsivity peak at a predetermined wavelength of an optical signal incident on the sensor. An embodiment also refers to an integration process of such a sensor, as well as to an ambient light sensor made with such a sensor.

### RELATED APPLICATION DATA

The instant application is a Divisional of U.S. patent application Ser. No. 12/649,256, filed Dec. 29, 2009 (Attorney Docket No. 2110-319-03 (06-CT-465), which claims priority to Italian Patent Application No. MI2008A002362, filed Dec. 31, 2008 and is related to commonly assigned and copending U.S. patent application Ser. No.12/649,248, (Attorney Docket no. 2110-318-03 (08-CT-132)), entitled SENSOR COMPRISING AT LEAST A VERTICAL DOUBLE JUNCTION PHOTODIODE, BEING INTEGRATED ON A SEMICONDUCTOR SUBSTRATE AND CORRESPONDING INTEGRATION PROCESS, filed on Dec. 29, 2009, which application is incorporated herein by reference in its entirety.

### TECHNICAL FIELD

An embodiment refers to a radiation sensor with photodiodes integrated on a semiconductor substrate.

More specifically an embodiment refers to a radiation sensor integrated on a semiconductor substrate and comprising at least one first and one second photodiode including at least one first and one second p-n junction made in said semiconductor substrate as well as at least one first and one second antireflection coating made on top of said first and second photodiodes.

An embodiment also refers to an integration process of such a radiation sensor with photodiodes integrated on a semiconductor substrate.

In particular, but not exclusively, an embodiment relates to a sensor with photodiodes integrated on a silicon semiconductor substrate suitable for making an ambient light sensor and the following description is made with reference to this field of application solely for purposes of example.

### BACKGROUND

As it is known, by the term radiation sensor or photodetector, devices suitable for detecting optical signals, in particular light, and for converting them into electrical signals are identified. Usually, such devices exploit the absorption coefficient of a specific material used for their manufacture.

In the case of semiconductor devices, the photons of the optical signal are absorbed by the silicon creating electron-hole pairs (based on the intrinsic transition phenomenon) if the energy of such photons is greater or equal to the energy of the forbidden band of the silicon (equal to 1.1 eV in the case of crystalline silicon).

If the energy of a photon is not sufficient, it may be absorbed anyway in the case in which there are energy states available in the band, in particular due to impurities or defects. This is the case of extrinsic transition.

It is known that the number of photons absorbed by a certain material at the distance Δx is given by: αφ(x)Δx, where α is the absorption coefficient of such a material and φ is the flow of photons incident on the material.

The absorption coefficients are a function of the wavelength. In the case of semiconducting materials, such coefficients may range from approximately 10³ to 10⁸ with wavelengths λ that range from approximately 0.2 to 1.8 μm.

The radiation sensors may be used in different applications, for example for making ambient light sensors (ALS). In this case, the radiation sensor is normally made with photodiodes in silicon, that is to say integrated on a semiconductor.

In particular, an ambient light sensor is a device designed to detect the intensity of the ambient light, in the most possible similar way to that of the sensitivity of the human eye. Such a device is normally used to calibrate the brightness of electronic devices according to the ambient light condition (backlight setting), for example to calibrate the backlight of screens, the brightness of displays or of numeric keypads, night time or household illumination, etc., all for the purpose of making the viewing of the electronic device in question as pleasant and efficient as possible for the human eye.

In particular, the use of ambient light sensors may allow an energy saving even of over 50% for the system in which they are mounted (so-called “power saving” function), all whilst optimizing the brightness of such a system (“autodimming” function) according to the required perception of the human eye according to the particular ambient condition.

As already stated, photodiodes, but also phototransistors, integrated on silicon are low-cost devices usually used to make a radiation sensor, in particular in the case of ambient light sensors.

An integrated photodiode is substantially formed from an inversely polarized pn junction made in a semiconductor substrate. More specifically, an asymmetrically doped p-n junction may be used, where the region p, i.e. the area doped with acceptors, is much more doped than the region n doped with donor atoms, to improve the response of the photodiode in some areas of the visible spectrum.

Indeed, the photodetection mainly involves two regions of the structure of a photodiode: one surface region, on which the light is incident, and a region of absorbing material, in particular silicon, where the p-n junction is made.

To function, the photodiode, and in particular its surface region, is exposed to light. Therefore, in such a surface region, materials that tend to reflect light should be avoided as much as possible, in particular metals, whereas antireflection materials are appropriately used to absorb as much light as possible from the incident radiation and to reduce to a minimum the reflected light.

In this way, the integrated photodiode, when hit by a light signal, generates electron-hole pairs within a diffusion length, and in the region of space charge the pairs are separated by an appropriate electric field and contribute to the generated photocurrent. For this the region of space charge is typically very large.

The electrons coming out from the region n are collected by an appropriate generator and injected into the region p, where they recombine with the holes photogenerated (in equal number). The photocurrent Ip thus created in the photodiode is proportionate to the number of electron-hole pairs generated and therefore to the number of photons of the optical signal that has hit the photodiode itself. In other words, a photodiode provides in output a current that is a function of the intensity of the light incident on it and by its amount, it is, therefore, possible to work out the illumination, for example of the environment in which the photodiode is placed, and then consequently, adapt the illumination conditions of the electronic device equipped with an ambient light sensor made up of such photodiodes.

One of the important parameters for a photodiode of this type is the quantum efficiency, that is to say the number of pairs generated for every incident photon, equal to:

$$η = ( \frac{{I}_{p}}{q} ) {( \frac{{P}_{opt}}{hv} )}^{- 1}$$

where:

η is the quantum efficiency

Ip is the photocurrent that flows through the photodiode;

q is the charge of an electron

Popt is the incident optical power

h is the Planck's constant

v is the frequency of the incident optical signal

The responsivity of the photodiode is also defined as the relationship between photocurrent Ip and incident optical power Popt.

In FIG. 1, (normalized) responsivity curves are shown as obtained experimentally in the case of photodiodes in silicon, in particular with a surface junction (curve R1) and a deep junction (curve R2), compared with the optical response of the human eye (curve ER), which, as is known, sensitive only to radiations of wavelengths approximately between 400 and 700 nm.

As may be worked out from such a figure, it is therefore possible to shift the peak of the responsivity curve of a silicon photodiode by changing the depth of the p-n junction that makes it, with respect to the surface of the semiconductor in which such a photodiode is made. In general, it is also possible to modify such a peak by varying the structural features of the p-n junction that makes the photodiode. It is difficult, however, to obtain a responsivity curve that coincides with the response of the human eye (curve ER in FIG. 1), in particular by zeroing the Substitute Specification response of the photodiode to ultraviolet radiation (UV) and radiation in the near infrared (IR), that is below about 400 nm and above about 700 nm.

To get close to such a result, one of the most popular solutions in ambient light sensors currently on the market is that of composing the signal from currents coming from two p-n junctions (that is to say from two different photodiodes) with different responsivity, as schematically shown in FIGS. 2A-2C. In particular the optical signals of such photodiodes with different responsivity PH1 and PH2 (FIG. 2A) are subtracted (FIG. 2B) obtaining a combined responsivity PHc of the type illustrated in FIG. 2C.

Also in this case, the different responsivity of the two photodiodes is usually obtained by differentiating the depth of the p-n junction that makes them. In that case it may also be called a double junction photodiode.

Although it is advantageous from some points of view, this known solution has a drawback of demanding precise and different doping steps of the integrated radiation sensor comprising the two photodiodes to obtain the necessary p-n junctions at different depths. It is therefore may be necessary to implement new implants in the technology in which such photodiodes are to be made.

### SUMMARY

An embodiment is realizing a radiation sensor with photodiodes, having structural and functional features such that it is not necessary to have junctions at different depths, overcoming in this way at least some of the limitations and drawbacks, that still now limit devices made according to the prior art, and making a sensor with responsivity as similar as possible to the response of the human eye.

An embodiment varies the responsivity of an integrated sensor thanks to the presence of different antireflection coatings on the photodiodes that make it, and that are integrated in a same chip, such a sensor being particularly suitable for making an ambient light sensor having a responsivity peak at approximately a sensitivity peak of the human eye.

In an embodiment, a sensor is integrated on a semiconductor substrate and comprises at least, one first and one second photodiode including at least one first and one second p-n junction made in said semiconductor substrate, as well as at least one first and one second antireflection coating made on top of said first and second photodiodes, wherein at least one antireflection coating of said first and second photodiodes comprises at least one first and one second different antireflection layer to make a double layer antireflection coating suitable for obtaining, for the corresponding photodiode, a responsivity peak at a predetermined wavelength of an optical signal incident on said sensor.

A sensor according to an embodiment has a responsivity peak corresponding to a sensitivity peak of the human eye, said predetermined wavelength (λ) being approximately equal to 540 nm.

According to an embodiment, said first antireflection layer is made of a dielectric layer with thickness equal to half of said predetermined wavelength and said second antireflection layer is made of a dielectric layer with thickness equal to one quarter of said predetermined wavelength.

In particular, said first antireflection dielectric layer may be silicon oxide and said second antireflection dielectric layer, silicon nitride.

According to an embodiment, the sensor may also comprise at least one first and one second contact structure for said first and second p-n junctions made in a structure with alternated intermetal dielectric layers and metallic layers.

Said first and second photodiodes may be pn junctions of any depth.

A sensor according to an embodiment may also comprise at least one metallic layer deposited on top of said semiconductor substrate and open at said junctions as well as at openings for contact structures of said first and second photodiodes.

According to an embodiment, the sensor may also comprise circuitry integrated in said semiconductor substrate and suitable for connecting said first and second photodiodes, said circuitry subtracting from a first electrical signal in output from a photodiode a second electrical signal in output from the other photodiode.

In particular, said circuitry may comprise at least one first and one second amplification block respectively connected to said first and second photodiodes to suitably weigh, through respective weight coefficients, said electrical signals before subtracting one from the other, so as to obtain said responsivity peak for said sensor at said approximate predetermined wavelength.

Suitably, said first and second amplification blocks may comprise respective current/tension conversion blocks of said electrical signals of said first and second photodiodes.

Said circuitry may also comprise a logic block connected to said first and second amplification block and suitable for amplifying and logically processing an output signal from said first and second amplification blocks so as to eliminate a possible negative signal difference obtaining an output signal.

Suitably, an embodiment of the circuitry may comprise at least:
a first current mirror made from a first and a second MOS transistor and connected between a first voltage reference and said first photodiode and a central circuit node;
a second current mirror made from a third and a fourth MOS transistor and connected between said second photodiode and said central circuit node and a second voltage reference; as well as
an operational amplifier inserted between said first and second voltage references and having a first input terminal, a second input terminal and an output terminal, said second input terminal being connected to said common circuit node and said output terminal being connected, in feedback, to said first inverting input terminal
   said first photodiode being connected between said first current mirror and said second voltage reference, and said second photodiode being connected between said first voltage reference and said second current mirror.

Suitably, in an embodiment, said first input terminal of said operational amplifier is connected through a first resistor to said second voltage reference, said output terminal of said operational amplifier is connected in feedback through a second resistor and said second input terminal of said operational amplifier is also connected to said second voltage reference through a third resistor.

Furthermore, in an embodiment, said first transistor of said first current mirror is configured as a diode and has a control terminal connected to a control Substitute Specification terminal of said second transistor of said first current mirror at a first inner circuit node and said third transistor of said second current mirror is configured as a diode and has a control terminal connected to a control terminal of said fourth transistor of said second current mirror at a second inner circuit node.

According to an embodiment, the control circuitry is possibly covered by a metallic layer suitable for protecting it from the incident light.

In an embodiment, an integration process of a sensor with photodiodes integrated into a multi-layer structure comprising a semiconductor substrate and an alternating structure of intermetal dielectric layers and metallic layers, as well as an upper passivation layer of the type comprising the steps of:
making in said semiconductor substrate at least one first and one second pn junction, suitable for making at least one first and one second photodiode;
removal of said intermetal dielectric layers and of said upper passivation layer at at least one opening suitable for uncovering a surface of said semiconductor substrate at said junctions,
deposition of a first antireflection dielectric layer for covering at least said surface; and
deposition on top of said first antireflection dielectric layer of a second antireflection dielectric layer to make a double layer antireflection coating suitable for obtaining a responsivity peak for the corresponding photodiode at a predetermined wavelength of an optical signal incident on said sensor.

Suitably, the deposition step of said first antireflection dielectric layer may comprise a deposition step of a dielectric layer having a thickness equal to approximately half of said predetermined wavelength and said deposition step of said second antireflection layer may comprise a deposition step of a dielectric layer having a thickness equal to approximately one quarter of said predetermined wavelength.

According to an embodiment, the deposition step of said first antireflection dielectric layer may comprise a deposition step of a layer of silicon oxide and said deposition step of said second antireflection layer may comprise a deposition step of a layer of silicon nitride.

Suitably, the process may comprise a step of making at least one first and one second contact structure for electrically connecting said first and second junctions, respectively, in said structure alternated with intermetal dielectric layers and metallic layers, said step also comprising a step of making openings for said first and second contact structure in a first metallic layer above said semiconductor substrate.

An integration process according to an embodiment may also comprise an etching step of said first and second antireflection dielectric layers and of said upper passivation layer at said first and second contact structures to make suitable openings for connecting to said first and second contact structures.

In particular, said removal step of said intermetal dielectric layers and of said upper passivation layer may comprise an etching selected from a dry, wet or dry and wet etching, for example, a combined dry and wet etching to obtain, for said opening, substantially perpendicular walls with respect to said surface of said semiconductor substrate.

An integration process according to an embodiment may comprise, after said deposition step of said first antireflection dielectric layer, a removal step by selective etching of said first antireflection dielectric layer for its removal only at one of said junctions, said deposition step of said second antireflection dielectric layer making said double layer antireflection coating only at the other one of said junctions.

Suitably, said selective etching step of said first antireflection dielectric layer may comprise a wet etching step.

An embodiment of an ambient light sensor may comprise at least one sensor of the aforementioned type.

### BRIEF DESCRIPTION OF THE DRAWINGS

Characteristics and advantages of the radiation sensor with photodiodes and of its integration process according to one or more embodiments shall become clear from the following description, of one or more examples given for illustrative and not limiting purposes with reference to the attached drawings.

In such drawings:

FIG. 1 shows (normalized) responsivity curves, experimentally obtained for silicon photodiodes made according to the prior art, compared to the response of the human eye;

FIGS. 2A-2C show a composition of a responsivity of the two silicon photodiodes made according to the prior art;

FIG. 3 schematically shows a sensor with photodiodes made according to an embodiment of the invention;

FIG. 4 shows the transmittance curves referring to layers of silicon oxide of different thickness;

FIG. 5 shows the transmittance spectrum of a double layer antireflection coating according to an embodiment of the invention;

FIG. 6 shows the responsivity patterns obtained by a sensor comprising a photodiode equipped with an antireflection coating consisting of just an oxide and a double layer antireflection coating according to an embodiment of the invention, respectively;

FIGS. 7A-7B show the results of an embodiment of a sensor with photodiodes made with p-n junctions in HCMOS4TZ technology;

FIG. 8 shows total responsivity curves obtained by composing the currents in output from the two photodiodes comprised in the sensor according to an embodiment of the invention compared to the response of the human eye;

FIGS. 9A-9E show a sensor according to an embodiment of the invention in different steps of its integration process, according to an embodiment thereof;

FIGS. 10A-10B show a sensor according to an embodiment of the invention in different steps of its integration process, according to an embodiment thereof;

FIG. 11 shows a circuit for a sensor with photodiodes according to an embodiment of the invention; and

FIG. 12 shows an embodiment of implementation of the circuit of FIG. 11.

### DETAILED DESCRIPTION

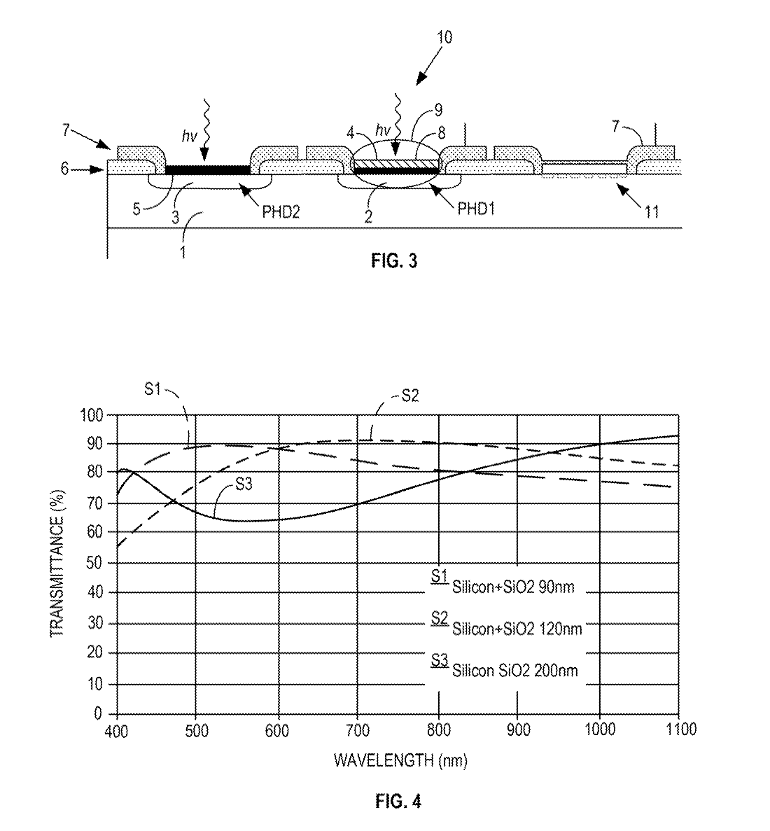

With reference to such figures, and in particular to FIG. 3, a radiation sensor or briefly, sensor 10, is described, being integrated on a semiconductor substrate 1 and comprising a first PHD1 and a second silicon photodiode PHD2, alternatively also indicated hereafter as a double junction photodiode.

More specifically, the sensor 10 comprises a first photodiode PHD1 and a second photodiode PHD2 being integrated in the semiconductor substrate 1 and comprising respective first and second p-n junctions 2 and 3, made through suitable doping in such a semiconductor substrate 1.

The photodiodes PHD1 and PHD2 also comprise respective portions 4 and 5 of a first antireflection layer, on top of the p-n junctions, 2 and 3 respectively.

The sensor 10 also comprises a layer 6 of silicon oxide suitably open at the p-n junctions 2 and 3, as well as a metallic layer 7 deposited on top of the oxide layer 6 and open at the portions 4 and 5 of the first antireflection layer, such oxide and metallic layers 6 and 7, being common in silicon integration technologies, suitably removed at sensor 10 according to an embodiment of the invention at an optical area thereof.

According to an embodiment of the invention, the sensor 10 also comprises a portion 8 of a second and different antireflection layer at one of such photodiodes, for example, at the first photodiode PHD1, arranged on top and at the portion 4 of the first antireflection layer to make a double layer antireflection coating 9

The sensor 10 also comprises at least one first and one second contact structure, 2A and 3A, for the p-n junctions, 2 and 3, of the photodiodes, PHD1 and PHD2, such contact structures being made in an alternating structure of intermetal dielectric layers 16 and metallic layers 17, as shall become clear in the rest of the description.

Furthermore, a circuit 11 is integrated into the semiconductor substrate 1, to make the connection between the first PHD1 and the second photodiode PHD2 of the sensor 10 in such a way that from a first signal, in particular in current, in output from the first photodiode PHD1, a second signal, in particular in current, in output from the second photodiode PHD2, is subtracted, as shall become clearer in the rest of the description. According to an embodiment, as shown for example in FIG. 3, the circuitry 11 is coated by a metallic layer 7 suitable for protecting it from incident light which could lead the devices that make it up, to malfunction. Indeed, it should be remembered that the circuitry 11 is usually coated by a layer of light colored coating resin (packaging) and it may need to be protected from light, something that is obtained very effectively by using the metallic layer 7.

Furthermore, according to an embodiment, the first and second antireflection layers 4 and 5 are selected in a suitable way to obtain a responsivity peak for the first photodiode PHD1 at a predetermined wavelength λ, for example approximately equal to 540 nm, in other words at approximately the sensitivity peak of the human eye.

It is noted that it is known to limit the losses due to the reflection of the electromagnetic radiation incident on the surface of a sensor 10, through integration of surface antireflection layers.

Usually, such antireflection layers are selected so as to have an optical thickness nd equal to one quarter of the wavelength λ of visible light (nd=λ/4), in order to have a maximum transmission at a peak wavelength λp of the desired responsivity.

In particular, FIG. 4 shows the transmittance curves referring to silicon oxide layers with different thicknesses, such layers being deposited on a silicon substrate like the semiconductor substrate 1 of the sensor 10.

The transmittance in this case indicates the percentage of light that may be absorbed by the sensor 10, taking into account the amount reflected by its surface and that possibly absorbed by the antireflection layers comprised therein.

In particular, it may be observed that the transmittance improves compared to the case in which the surface of the sensor 10 is only silicon.

It may also be observed that the antireflection layers have low transmittance in ultraviolet (UV) because of the absorption of the oxide layer in such a region. In the visible range, on the other hand, the transmittance stays between 80 and 95%. The selection of the thickness of the oxide layer to be used depends on the final application of the sensor 10, even if it does not have much effect on the form of the responsivity pattern, but rather on the intensity of the photocurrent generated.

It is also worth highlighting the fact that the transmittance curves of FIG. 4, referring to a silicon oxide layer deposited on a semiconductor substrate, may also correspond in realty to any other layer or film having low absorption, such as for example ZnO, SiN, MgS, etc. . . . in the range of wavelengths as considered.

According to an embodiment of the invention, the use of a double antireflection layer deposited on the first photodiode PHD1 allows its responsivity to be profoundly modified.

In particular, in an embodiment of the sensor 10, the first photodiode PHD1 comprises a portion 4 of a first antireflection layer 14 made from silicon oxide with a thickness equal to approximately λ/2n (in other words equal to approximately half of the wavelength λ=540 nm that corresponds to 1900 A) under a portion 8 of a second antireflection layer 15 made from silicon nitride (SiN) with a thickness equal to approximately A/4n to form the double layer antireflection coating 9. It is possible to use different antireflection layers, that is to say not necessarily made from silicon oxide and nitride, but generally made from dielectric layers with thicknesses respectively about λ/2n and about λ/4n.

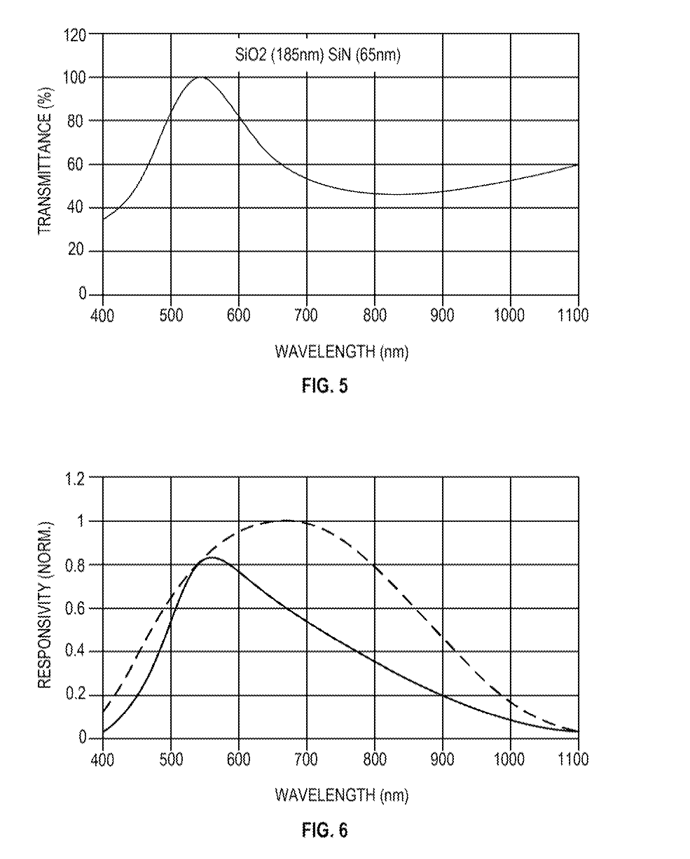

The transmittance spectrum of such a double layer antireflection coating 9 (simulated as a silicon nitride-oxide pair deposited on a silicon semiconductor substrate) is illustrated in FIG. 5 and shows a significant increase of the transmittance in the visible range.

In greater detail, the double layer antireflection coating 9 according to an embodiment of the invention has a transmittance peak at approximately λ=540 nm and a width at half height of about 200 nm, similar characteristics to the response of the human eye.

FIG. 6 shows the responsivity curves obtained by a sensor 10 comprising a photodiode equipped with an antireflection coating having just an oxide having a thickness equal to approximately 2000 A (curve shown with a dashed line) or by a double layer antireflection coating 9 comprising an oxide-nitride pair as described above (curve shown with a continuous line). In particular, the sensor 10 is in BCD3 technology.

It may be seen that the presence of the double layer antireflection coating 9 functions as a filter for the ultraviolet (UV) component and significantly shifts the responsivity peak to approximately the desired wavelength, in the case of interest equal to 540 nm corresponding to the response peak of the human eye.

Suitably, the thicknesses of the portions 4 and 8 of such first and second antireflection layers of the double layer antireflection coating 9 may be selected based upon the following table:

TABLE I

| Layer | λ = 540 nm |
|---|---|
| Thickness of SiO₂ = λ/2n | Approximately 190 nm |
| (n = 1.45) | |
| Thickness of Si₃N₄ = λ/4n | Approximately 70 nm |
| (n = 2) | |

(n is the approximate index of refraction for the indicated materials)

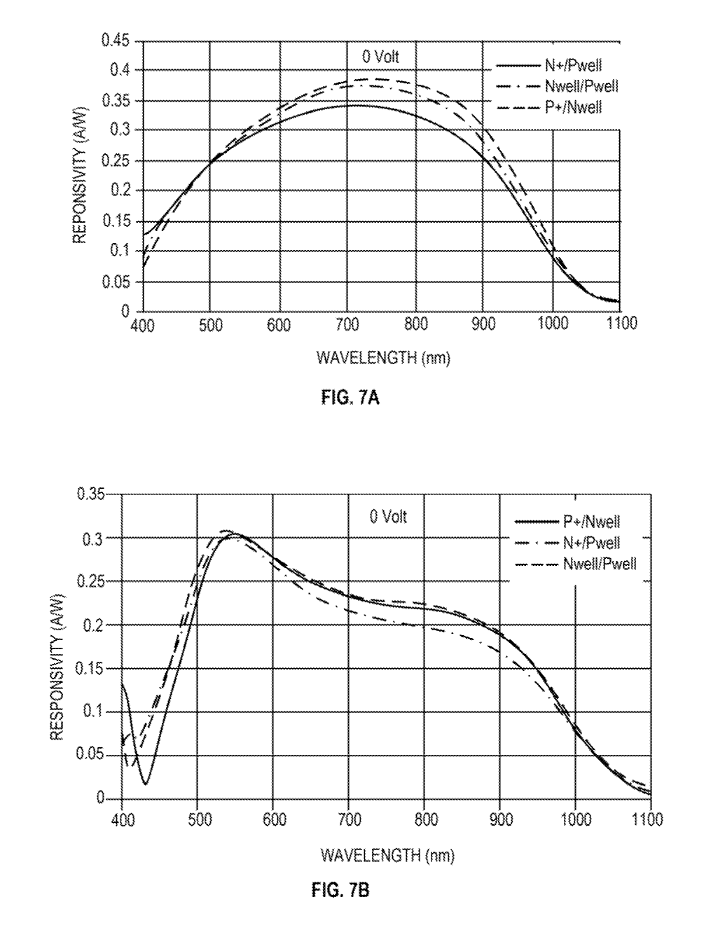

Sensors with photodiodes made through p-n junctions in HCMOS4TZ technology have been characterized. The responsivity curves as obtained through such characterisation are illustrated in FIGS. 7A and 7B.

In particular, FIG. 7A shows the responsivity curves of three different junctions, respectively of the N+/Pwell, Nwell/Pwell and P+/Nwell type, that comprise a layer of silicon oxide having a thickness equal to approximately 1000 A as an antireflection layer, whereas FIG. 7B shows the responsivity curves referring to the same junctions, but in this case comprising a double layer antireflection coating 9 (SiO2/SiN). The data has been acquired in the same polarization configurations of such junctions.

It may be seen that the responsivity curve of the junctions clearly changes in presence of the double layer antireflection coating 9. In particular, the antireflection layer made up of the silicon nitride/oxide pair keeps the characteristics already indicated and shifts the responsivity peak from about 740 nm to about 540 nm.

It is worth highlighting the fact that the curves illustrated in FIG. 7B differ from that of FIG. 6 since they refer to substantially different sensors, even though once again there is the aforementioned shifting of the responsivity peak.

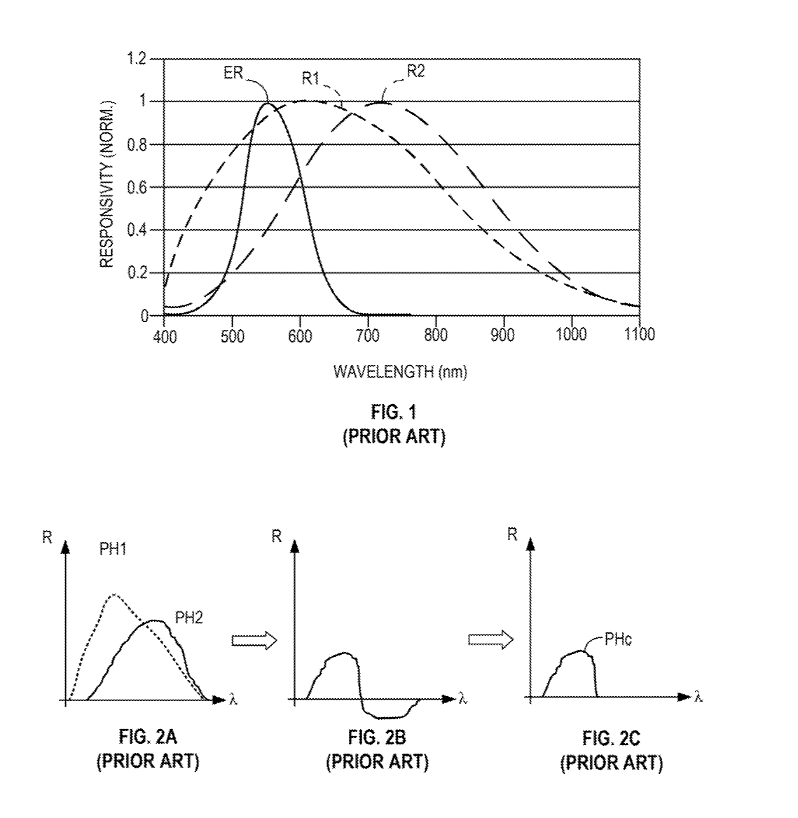

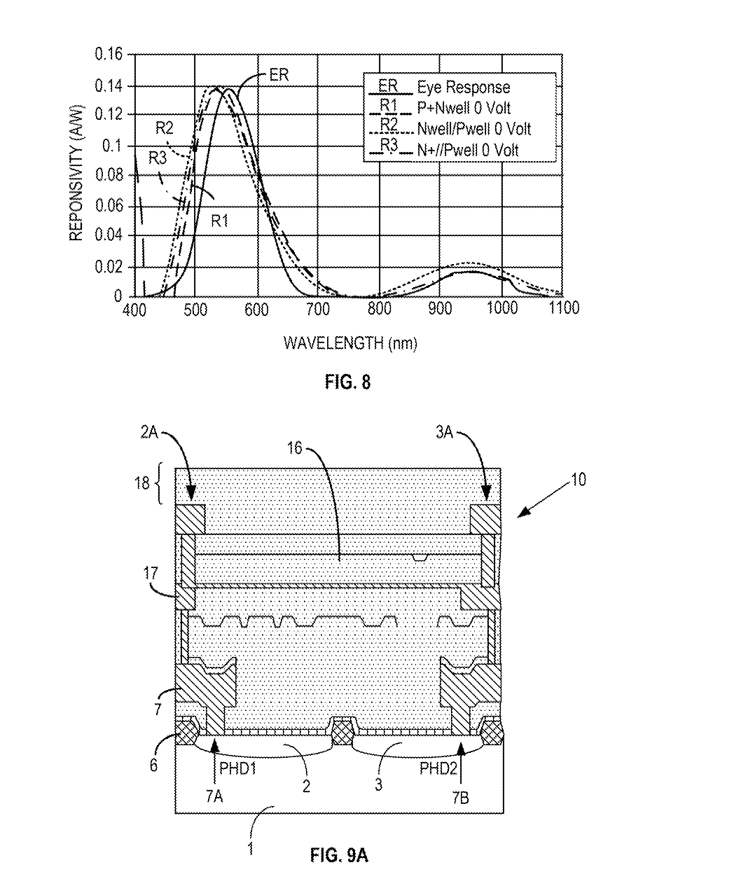

The variation of the responsivity peak is the thing that, making up the currents in output from the two photodiodes comprised into the sensor 10 (as previously explained and represented in FIGS. 2A-2C), makes it possible to obtain total responsivity curves of the type illustrated in FIG. 8, where the responsivity curve of the human eye (curve ER) is also shown.

It may be seen that, according to an embodiment, by using the double layer antireflection coating 9 on the first photodiode PHD1 of the sensor 10 and by making up the currents in output from the two photodiodes comprised therein, it is possible to obtain responsivity curves appreciably close to that of the human eye.

To obtain the curves as shown in FIG. 8, it may be necessary to suitably define the areas of the two photodiodes PHD1 and PHD2 of the sensor 10.

In particular, in the case the results of which are shown in FIG. 8, a ratio between the areas equal to approximately 2.85 was considered. Indeed, such a ratio between the areas allows the peak of responsivity curves at about 950 nm (see FIG. 7B) to be substantially eliminated.

An embodiment of the present invention also refers to an integration process of a sensor 10 of the aforementioned type. In particular, the process comprises an integration step of the first and second antireflection layers of the sensor only at the end of the manufacturing steps of the wafer in which the sensor is made.

As shall become clear in the rest of the description, the integration step of the antireflection layers comprises low thermal budget depositions and therefore does not have an impact on the technology used for the development of the circuitry 11. Furthermore, even though later on in the following description an embodiment of a sensor 10 comprising a couple of junction photodiodes will be referred to, an embodiment of the process may be used for any type of sensor, for example comprising pin diodes, transistors, and whatever else.

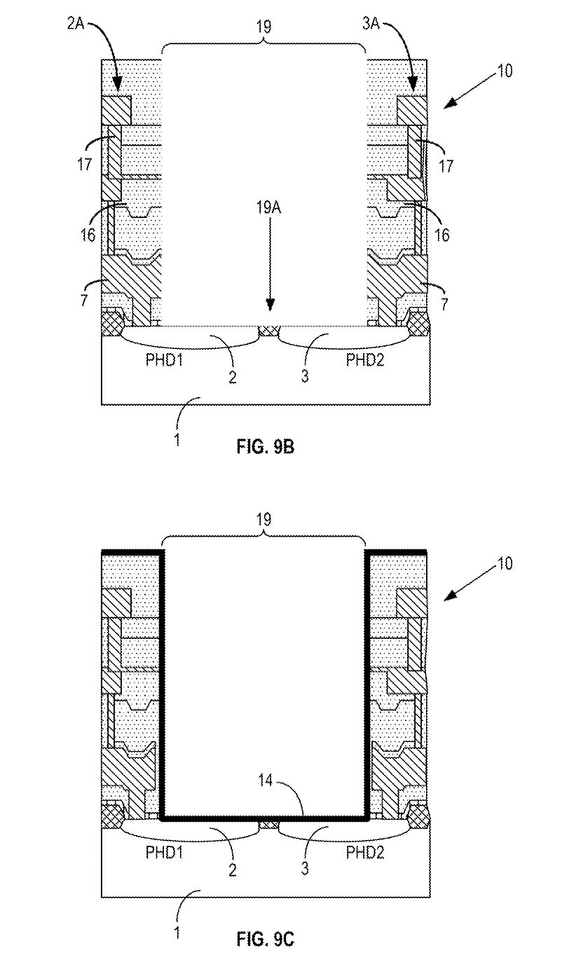

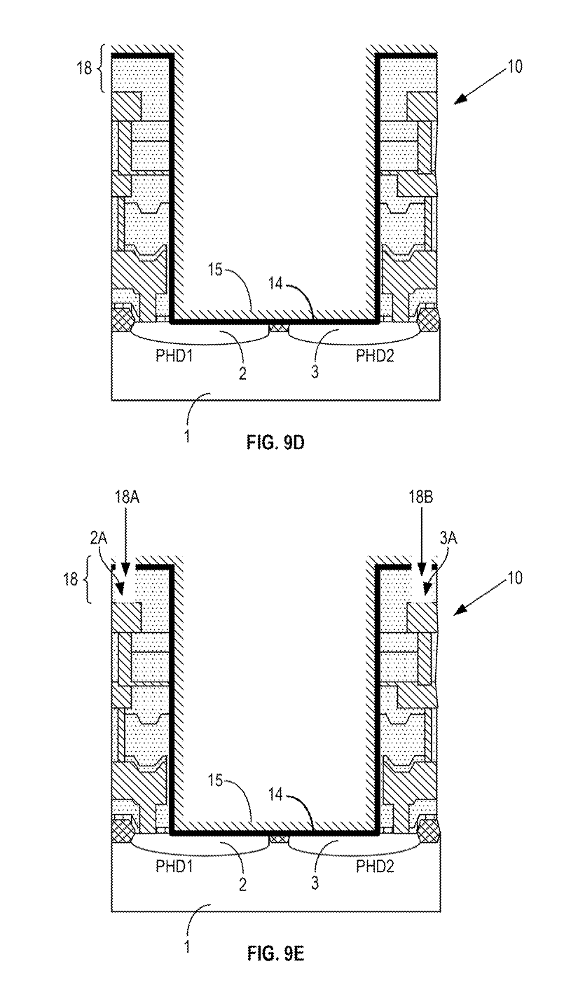

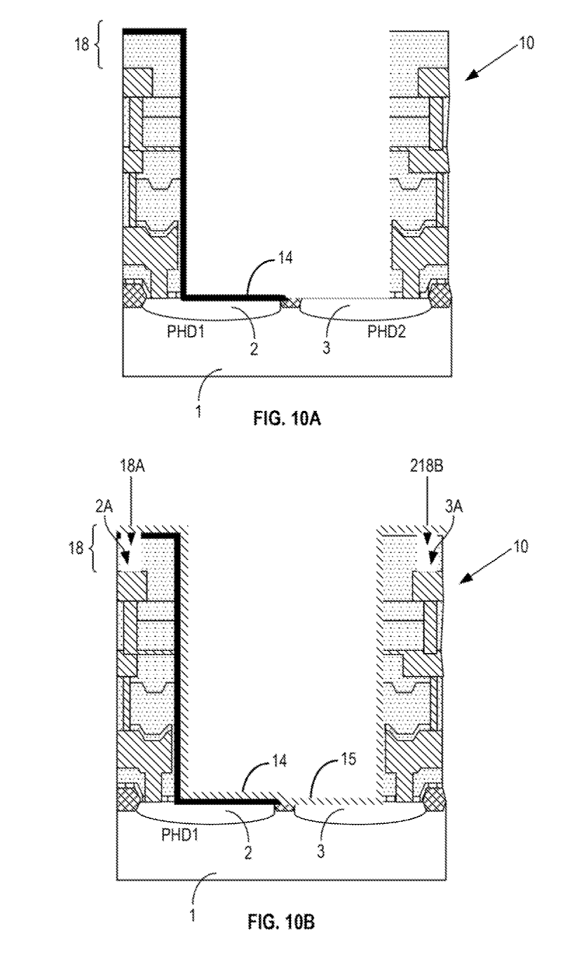

An integration process of the sensor 10 is later on illustrated with reference to FIGS. 9A to 9E and to FIGS. 10A and 10B with reference to respective first and second embodiments thereof.

It is noted that the process steps described hereafter do not form a complete process flow for the manufacture of integrated circuits. An embodiment of the present invention may be put into practice together with the manufacturing techniques of integrated circuits currently used in this field, and only the steps of the process commonly used and necessary to understand the embodiment(s) are included.

Furthermore, the figures that represent schematic views of portions of an integrated circuit during the manufacture are not drawn to scale, but instead are drawn so as to emphasize one or more important characteristics of one or more embodiments of the invention.

In particular, as illustrated in FIG. 9A, an integration process of the sensor 10 in a multi-layer structure comprising a semiconductor substrate 1 and an alternating structure of intermetal dielectric layers 16 and metallic layers 17, as well as an upper passivation layer 18 according to an embodiment of the invention comprises the steps of:
making, in such a semiconductor substrate 1, at least the first and second pn junctions 2 and 3, suitable for making at least one first PHD1 and one second photodiode PHD2 and separated by portions of the oxide layer 6; and
making at least one first 2A and one second contact structure 3A for electrically connecting the first and second junctions, 2 and 3, respectively, in the alternating structure of intermetal dielectric layers 16 and metallic layers 17 and in the upper passivation layer 18.

In particular, in the example illustrated in FIG. 9A, the sensor 10 comprises three metallic layers 17 and just as many intermetal dielectric layers 16, as well as an upper passivation layer 18.

Furthermore, again as an example, the sensor 10 illustrated in FIG. 9A comprises two junctions 2 and 3 substantially the same as each other. Suitably, thanks to the fact that first openings 7A and 7B are made for the contact with the junctions 2 and 3, the active area of such junctions 2 and 3 may be left as uncovered as possible by metallizations, so as to make the electrical area coincide, as much as possible, with the optical area of the sensor 10, the layers at the active areas of such junctions 2 and 3 therefore mainly being the intermetal dielectric layers 16, as illustrated in FIG. 9A.

According to an embodiment, the process therefore comprises a removal step of the intermetal dielectric layers 16 and of the upper passivation layer 18 at an opening 19 made in such intermetal dielectric layers 16 and suitable for uncovering a silicon surface 19A at the junctions 2 and 3, as illustrated in FIG. 9B.

In particular, such a removal step of the intermetal dielectric layers 16 and of the upper passivation layer 18 comprises an etching selected from a dry, wet or dry, and wet etching.

It is worth remembering that such intermetal dielectric layers 16 and upper passivation layer 18 may be standard layers of the silicon integration technologies.

In an embodiment of the invention, the removal step comprises a dry and wet etching, that allows substantially vertical walls, in other words substantially perpendicular to the surface 19A, to be obtained for the opening 19, such a silicon surface 19A also being less damaged compared to just a wet etching thanks to the combined presence of the dry etching with the wet etching.

Furthermore, an embodiment of the process comprises a deposition step of the first antireflection dielectric layer 14 with a thickness of approximately λ/2n, where λ is the wavelength equal to about 540 nm which corresponds to 1900 A, covering at least the surface 19A, as illustrated in FIG. 9C.

In particular, the first antireflection dielectric layer 14 may be made from silicon oxide.

The step of making the opening 19 may be designed so that most of the active area of the two junctions 2 and 3, corresponding to the two photodiodes PHD1 and PHD2 that make the sensor 10, is only covered by such first antireflection dielectric layer 14.

An embodiment comprises a further deposition step of a second antireflection dielectric layer 15 having a thickness of approximately λ/4n, as illustrated in FIG. 9D.

In particular, the second antireflection dielectric layer 15 may be made from silicon nitride.

An embodiment of the process then comprises an etching step of the dielectric antireflection layers 14 and 15 and of the upper passivation layer 18 at the contact structures 2A and 3A to make suitable openings 18A and 18B for connecting to such contact structures 2A and 3A, as illustrated in FIG. 9E.

Now referring to FIGS. 10A and 10B, another embodiment of the process is described.

In particular, after the deposition step of the first antireflection dielectric layer 14, the process in this embodiment comprises a removal step by selective etching of such a first antireflection dielectric layer 14, as illustrated in FIG. 10A.

More specifically, the first antireflection dielectric layer 14 is removed only at one junction, in particular at the second junction 3, in other words at the second photodiode PHD2.

Indeed, in this way, according to an embodiment, two different responsivity signals are obtained from the two integrated photodiodes, that are easy to manipulate so as to obtain a responsivity similar to the response of the human eye to make the desired sensor 10.

In particular, the removal step of the first antireflection dielectric layer 14 may comprise a wet etching.

According to an embodiment, the process then comprises a further deposition step of the second antireflection dielectric layer 15 having a thickness of about λ/4n, as illustrated in FIG. 10B. In particular, such a second antireflection dielectric layer 15 lays on the first antireflection dielectric layer 14 at the first junction 2, in other words at the first photodiode PHD1, which therefore is equipped with a double layer antireflection coating.

In particular, the second antireflection dielectric layer 15 may be made from silicon nitride.

The process may then comprise an etching step of the antireflection dielectric layers 14 and 15 and of the upper passivation layer 18 at the contact structures 2A and 3A to make suitable openings 18A and 18B for connecting to such contact structures 2A and 3A, as illustrated in FIG. 10B.

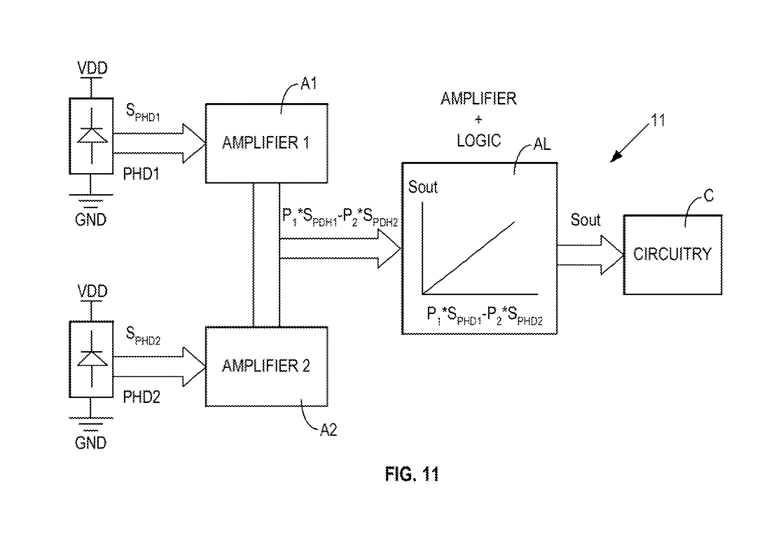

The sensor 10 may also comprise a circuit 11 as illustrated in FIG. 11.

Such circuitry may be used to suitably combine the photocurrents in output from the photodiodes of the sensor 10, reprocessing such signals to obtain a response close to that of the human eye.

In particular, so that the combined response of two photodiodes or generically sensors may create an ambient light sensor or ALS, the photocurrents of the two photodiodes PHD1 and PHD2 may be suitably weighed. The relationship between photocurrent and Responsivity in a sensor may be expressed as follows:

I(λ)=R(λ)P(λ) (1)

where I(λ) is the generated photocurrent, R(λ) is the responsivity expressed in [A/W] and P(λ) is the power of the light incident on the sensor, all these parameters being determined at a given wavelength (λ).

The current I obtained at the moment in which a sensor is subjected to an incident light, having a given spectrum that extends between two wavelengths λ1 and λ2, is given by:

$$I = {\int }_{{λ}_{1}}^{{λ}_{2}} R ( λ ) P ( λ ) d λ \qquad ( 2 )$$

where R(λ) is the responsivity of the sensor and P(λ) is the power of the light incident on it.

By introducing in such an expression the definition of power density p(λ) given by:

$$p ( λ ) = \frac{P ( λ )}{A} \qquad ( 3 )$$

Where A is the area of the sensor, the following is obtained:

$$I = A {\int }_{{λ}_{1}}^{{λ}_{2}} R ( λ ) p ( λ ) d λ \qquad ( 4 )$$

In the case of a sensor 10 according to an embodiment of the invention made through two photodiodes, one may algebraically combine the photocurrents generated by such photodiodes, suitably weighed, so that the overall photocurrent may be comparable to that of an ambient light sensor or ALS the responsivity of which is as close as possible to that of the human eye.

According to an embodiment of the invention, the circuit 11 suitably amplifies the photocurrents of the photodiodes PHD1 and PHD2 to obtain the desired responsivity for the sensor 10.

In particular, the photodiodes PHD1 and PHD2 provide respective electric information signals S_{PHD1} and S_{PHD2}, in particular the generated photocurrent, to respective amplification blocks A1 and A2 that provide for weighing such signals and for subtracting one from the other obtaining a signal difference Sd in output equal to:

Sd=P₁*S_{PHD1}−P₂*S_{PHD2} (5)

where P₁ and P₂ are the weights applied by the amplification blocks A1 and A2, respectively.

It is also possible to operate with signals in voltage, providing respective current/voltage conversion blocks for the photodiodes PHD1 and PHD2.

The signal difference Sd is sent to a logic block AL where when needed it is amplified and subjected to a logic so as to eliminate a possible negative signal difference, obtaining an output signal Sout suitably sent to the application that uses the sensor 10, generically indicated as circuitry C.

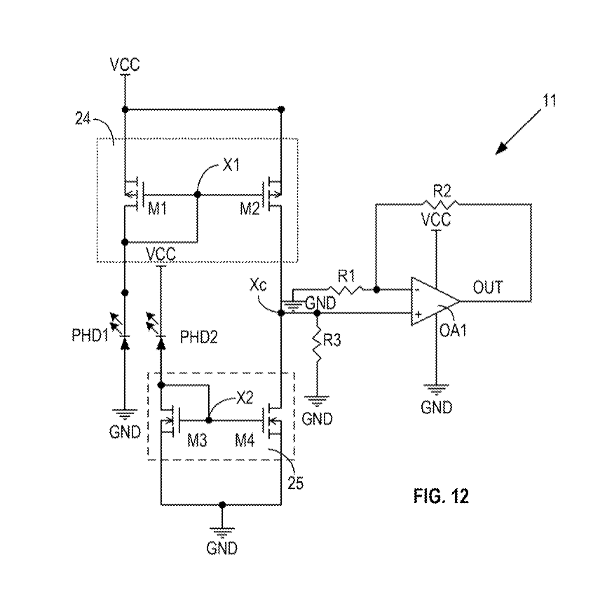

A possible circuit implementation of the circuitry 11 is illustrated in FIG. 12.

In particular, the circuit 11 may comprise:
a first current mirror 24 made by a first and a second MOS transistor M1, M2 and connected between a first voltage reference, in particular a power supply voltage reference Vcc and, respectively, the first photodiode PHD1 and a central circuit node Xc; in particular, the first transistor M1 is diode-configured and has the control or gate terminal connected to the control or gate terminal of the second transistor M2 at a first inner circuit node X1; and
a second current mirror 25 made by a third and a fourth MOS transistor M3 M4 and respectively connected between the second photodiode PHD2 and the central circuit node Xc and a second voltage reference, in particular a ground GND; in particular, the third transistor M3 is diode-configured and has the control or gate terminal connected to the control or gate terminal of the fourth transistor M4 at a second inner circuit node X2.

Furthermore, the first photodiode PHD1 is connected between the first current mirror 24 and the ground GND, whereas the second photodiode PHD2 is connected between the power supply voltage reference Vcc and the second current mirror 25.

The circuit 11 may also comprise an operational amplifier OA1 inserted between the power supply voltage reference Vcc and the ground GND and having a first input terminal, in particular inverting (−), connected, through a first resistor R1 to the ground GND, a second input terminal, in particular non inverting (+) connected to the common circuit node Xc, and an output terminal OUT connected, in feedback through a second resistor R2, to the first inverting input terminal (−). Furthermore, the second non-inverting input terminal (+) is in turn connected to the ground GND through a third resistor R3.

In particular, the two current mirrors 24 and 25, with suitable mirroring factors, are used for suitably weighing the photocurrents in output from the photodiodes PHD1 and PHD, whereas the third resistor R3 converts a value of total photocurrent at the common circuit node Xc, into voltage.

The operational amplifier OA1 has the dual function of amplifying such a signal in voltage, and of providing a zero voltage, in the case in which the overall photocurrent is negative, in this way acting as the logic of the circuitry 11 and illustrated, with reference to the prior art, in FIG. 2C.

It may be seen that the expression of the photocurrent in the common circuit node Xc is given by:

$$\begin{matrix}\begin{matrix}{I}_{TOT} = {P}_{1} {I}_{1} - {P}_{2} {I}_{2} \\ = {\int }_{{λ}_{1}}^{{λ}_{2}} {P}_{1} {A}_{1} {R}_{1} ( λ ) p ( λ ) d λ - {\int }_{{λ}_{1}}^{{λ}_{2}} {P}_{2} {A}_{2} {R}_{2} ( λ ) p ( λ ) d λ \\ = {\int }_{{λ}_{1}}^{{λ}_{2}} [ {P}_{1} {A}_{1} {R}_{1} ( λ ) - {P}_{2} {A}_{2} {R}_{2} ( λ ) ] p ( λ ) d λ \\ = {\int }_{{λ}_{1}}^{{λ}_{2}} [ {A}_{3} {R}_{3} ( λ ) ] p ( λ ) d λ\end{matrix} & \\ with \\ {P}_{1} {A}_{1} {R}_{1} ( λ ) - {P}_{2} {A}_{2} {R}_{2} ( λ ) = {A}_{3} {R}_{3} ( λ ) & \end{matrix}$$

where P1 and P2 are the weights applied by the current mirrors 24 and 25 and A1 and A2 are the minimum areas to be used by the photodiodes PHD1 and PHD2 in order to provide a photocurrent distinguishable from the noise and that may be managed by the electronic circuits connected to the sensor 10.

From the expressions shown above, it may be gathered that the global current generated by two photodetectors with areas A1 and A2, the currents of which are weighed by P1 and P2, is equivalent to that generated by a single ambient light sensor or ALS, the responsivity of which is R3(λ) and the area of which is A3.

Alternatively, it is possible to consider to act upon the size of the areas of the photodiodes, since, once the technology has been set, the responsivity does not change, whereas, as the active area increases, the photocurrent also increases. Such a hardware implementation solution may not, however, allow an optimization in terms of area minimization of the photodiodes.

An embodiment of the present invention also refers to an ambient light sensor or ALS made through the sensor 10 as described above.

In particular, a radiation sensor according to an embodiment of the invention allows an ambient light sensor with a responsivity curve close to that of the human eye to be made.

According to an embodiment of the invention, such a shift of the responsivity curve is obtained by using a structure with two photodiodes on which at least one double layer coating is deposited, that is to say, comprising a silicon nitride-oxide pair, on at least one of the junctions that make such photodiodes.

It is noted that a sensor according to an embodiment of the invention may have the same basic structure as the sensors made according to the prior art, therefore allowing a substantial saving in terms of investment from a technological point of view. Furthermore, such junctions may be made simultaneously.

It is also noted that, in an embodiment of the invention, the double layer antireflection coating comprises a first antireflection dielectric layer and a second antireflection dielectric layer, the latter being common to the two junctions that make the photodiodes. In this way, since the initial responsivity curve of the two junctions, before the deposition of the coating, is approximately the same as in the infrared region, except for the different area factor, the two photodiodes have similar responsivity curves and therefore the composition of the photocurrents in output from them may be more advantageous.

Furthermore, a process according to an embodiment of the invention may be integrated in any technology.

An advantage of the sensor 10 according to an embodiment of the invention, is that the use of a double layer antireflection coating allows the responsivity curve of the photodiodes to be profoundly modified. It is also possible, by suitably designing such a double layer antireflection coating, to use it working as a filter of the ultraviolet (UV) component, significantly shifting the responsivity peak to the desired wavelength, in particular equal to about 540 nm.

A further advantage of an embodiment of a sensor and of a process for making the sensor is the fact that the integration step of the antireflection layers for the photodiodes may be carried out at the end of the manufacturing process of the wafer that comprises the sensor itself. Moreover, being depositions that do not imply high thermal budget, the integration of such antireflection layers may not have an impact on the technology used for the development of the circuitry of the sensor.

Of course, in order to satisfy contingent and specific requirements, one may make numerous modifications and variants to the sensor and integration process described above, all covered by the spirit and scope of the disclosure.

In this way it is highlighted that the double antireflection layer as described above in relation to the application of the sensor as an ambient light sensor, may be extended to other radiation sensors, in particular in the region of silicon absorption.

Furthermore, a sensor circuit as described above may be coupled to another integrated circuit, such as a controller, to form a system. The sensor circuit and other IC may be disposed on the same or different integrated-circuit dies.

1-8. (canceled)

9. Integration process of a sensor with photodiodes being integrated in a multi-layer structure comprising a semiconductor substrate and a structure of alternating intermetal dielectric layers and metallic layers, as well as an upper passivation layer of the type comprising the steps of:
making at least one first and one second pn junction, suitable for making at least one first and one second photodiode in said semiconductor substrate;
removal of said intermetal dielectric layers and of said upper passivation layer at at least one opening suitable for uncovering a surface of said semiconductor substrate at said junctions,
deposition of a first antireflection dielectric layer covering at least said surface; and
deposition on top of said first antireflection dielectric layer of a second antireflection dielectric layer to make a double layer antireflection coating suitable for obtaining a responsivity peak for the corresponding photodiode at a predetermined wavelength of an optical signal incident on said sensor.

10. Integration process according to claim 9, wherein said deposition step of said first antireflection dielectric layer comprises a deposition step of a dielectric layer having a thickness equal to about half of said predetermined wavelength and in that said deposition step of said second antireflection layer comprises a deposition step of a dielectric layer having a thickness equal to about a quarter of said predetermined wavelength.

11. Integration process according to claim 10, wherein said deposition step of said first antireflection dielectric layer comprises a deposition step of a layer of silicon oxide and in that said deposition step of said second antireflection layer comprises a deposition step of a layer of silicon nitride.

12. Integration process according to claim 9, wherein said removal step of said intermetal dielectric layers and of said upper passivation layer comprises an etching selected from a dry, wet or dry, and wet etching.

13. Integration process according to claim 9, wherein said removal step of said intermetal dielectric layers and of said upper passivation layer comprises a combined dry and wet etching to obtain, for said opening, substantially perpendicular walls with respect to said surface of said semiconductor substrate.

14. Integration process according to claim 9, further comprising, after said deposition step of said first antireflection dielectric layer, a removal step by selective etching of said first antireflection dielectric layer for its removal only at one of said junctions, said deposition step of said second antireflection dielectric layer making said double layer antireflection coating only at the other of said junctions.

15. Integration process according to claim 9, wherein said selective etching step of said first antireflection dielectric layer comprises a wet etching step.

16-47. (canceled)

48. A method, comprising:
receiving a first wavelength of electromagnetic radiation through a first antireflective layer having a first thickness and through a second antireflective layer having a second thickness that is different than the first thickness;
receiving a second wavelength of electromagnetic radiation through a third antireflective layer;
generating a first signal across a first p-n junction in response to the received first wavelength; and
generating a second signal across a second p-n junction in response to the received second wavelength.

49. The method of claim 48 wherein the first thickness is less than the second thickness.

50. The method of claim 48 wherein:
the first thickness is approximately equal to one fourth of the first wavelength; and
the second thickness is approximately equal to one half of the second wavelength.

51. The method of claim 48 wherein the third antireflective layer has a third thickness that is approximately the same as the first thickness.

52. The method of claim 48, further comprising controlling a brightness level in response to a combination of the first and second signals.

53. The method of claim 48, further comprising controlling a brightness level in response to a difference between the first and second signals.

54. The method of claim 48, further comprising combining the first and second signals such that no value of the combined signal has particular polarity.

55. The method of claim 48, further comprising:
wherein the first signal comprises a first current;
wherein the second signal comprises a second current;
sinking a third current derived from one of the first and second currents to a node; and
sourcing a fourth current derived from the other of the first and second currents to the node.

56. The method of claim 55 wherein:
the third current is equal to the one of the first and second currents; and
the fourth current is equal to the other of the first and second currents.

57. The method of claim 55 wherein the first wavelength equals the second wavelength.
